(19) United States
(12) Patent Application Publication
(10) Pub. No.: US 2026/0291175 A1
(43) Pub. Date: Sep. 24, 2026

(54) SURFACE-EMITTING LASER

(71) Applicant: Kabushiki Kaisha Toshiba, Kawasaki-shi (JP)

(72) Inventors: Tetsuya Miyagawa, Yokohama Kanagawa (JP); Rei Hashimoto, Edogawa Tokyo (JP); Shinji Saito, Yokohama Kanagawa (JP); Kei Kaneko, Yokohama Kanagawa (JP); Tsutomu Kakuno, Fujisawa Kanagawa (JP); Masatoshi Hirono, Yokohama Kanagawa (JP)

(21) Appl. No.: 19/445,182

(22) Filed: Jan. 9, 2026

(30) Foreign Application Priority Data
Mar. 21, 2025 (JP) 2025-046731

(51) Int. Cl. H01S 5/042; H01S 5/11; H01S 5/183

(52) U.S. Cl. CPC H01S 5/04256; H01S 5/04252; H01S 5/11; H01S 5/18305

(57) ABSTRACT

According to one embodiment, a surface-emitting laser includes a first electrode, a second electrode, and a stacked body provided between the first electrode and the second electrode in a first direction from the first electrode to the second electrode. The stacked body includes a base, a light-emitting layer provided between the base and the second electrode and configured to emit a first light including a component having a first wavelength, and a photonic crystal layer provided between the light-emitting layer and the second electrode. The second electrode portion is provided around the first electrode portion along the first plane. The first electrode portion includes a first conductive layer and a second conductive layer. A second optical absorptance of the second conductive layer at the first wavelength is higher than a fourth optical absorptance of the fourth conductive layer at the first wavelength.

### CROSS-REFERENCE TO RELATED APPLICATIONS

This application is based upon and claims the benefit of priority from Japanese Patent Application No. 2025-046731, filed on Mar. 21, 2025; the entire contents of which are incorporated herein by reference.

### FIELD

Embodiments described herein relate generally to a surface-emitting laser.

### BACKGROUND

For example, in surface-emitting lasers and the like, improvements in characteristics are desired.

### BRIEF DESCRIPTION OF THE DRAWINGS

FIG. 1 is a schematic cross-sectional view illustrating a surface-emitting laser according to a first embodiment;

FIG. 2 is a schematic plan view illustrating the surface-emitting laser according to the first embodiment;

FIG. 3 is a schematic cross-sectional view illustrating a surface-emitting laser according to the first embodiment;

FIG. 4 is a schematic cross-sectional view illustrating a part of the surface-emitting laser according to the first embodiment; and

FIG. 5 is a schematic cross-sectional view illustrating a surface-emitting laser according to a second embodiment.

### DETAILED DESCRIPTION

According to one embodiment, a surface-emitting laser includes a first electrode, a second electrode, and a stacked body provided between the first electrode and the second electrode in a first direction from the first electrode to the second electrode. The stacked body includes a base, a light-emitting layer provided between the base and the second electrode and configured to emit a first light including a component having a first wavelength, and a photonic crystal layer provided between the light-emitting layer and the second electrode. The light-emitting layer is along a first plane crossing the first direction. The first electrode includes a first electrode portion and a second electrode portion. The second electrode portion is provided around the first electrode portion along the first plane. The first electrode portion includes a first conductive layer and a second conductive layer. The second conductive layer is between the first conductive layer and the base. The second electrode portion includes a third conductive layer and a fourth conductive layer. The fourth conductive layer is between the third conductive layer and the base. A second optical absorptance of the second conductive layer at the first wavelength is higher than a fourth optical absorptance of the fourth conductive layer at the first wavelength.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

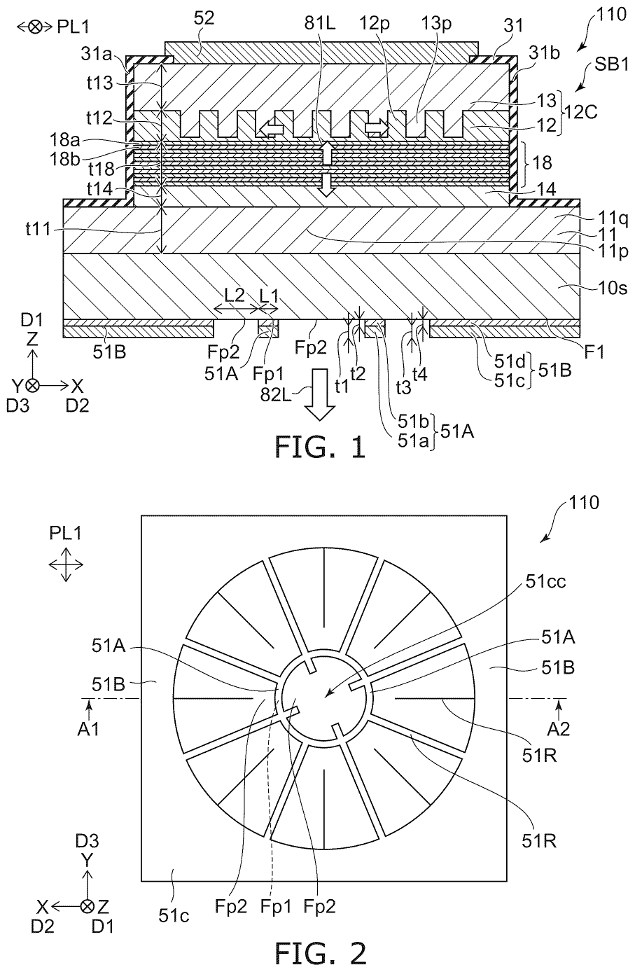

FIG. 1 is a schematic cross-sectional view illustrating a surface-emitting laser according to a first embodiment.

FIG. 2 is a schematic plan view illustrating the surface-emitting laser according to the first embodiment.

FIG. 1 is a cross-sectional view taken along the line A1-A2 in FIG. 2.

As shown in FIGS. 1 and 2, a surface-emitting laser 110 according to the embodiment includes a first electrode 51, a second electrode 52, and a stacked body SB1. The stacked body SB1 is provided between the first electrode 51 and the second electrode 52 in a first direction D1 from the first electrode 51 to the second electrode 52.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The stacked body SB1 includes a base 10s, a light-emitting layer 18, and a photonic crystal layer 12C. The light-emitting layer 18 is provided between the base 10s and the second electrode 52. The light-emitting layer 18 is configured to emit a first light 81L including a component having a first wavelength λ1.

The photonic crystal layer 12C is provided between the light-emitting layer 18 and the second electrode 52. The first light 81L incident on the photonic crystal layer 12C spreads along the X-Y plane. The spread light is emitted to the outside from the side of the base 10s. For example, light generated in the left-right direction in FIG. 1 is twisted in the vertical direction in FIG. 1 due to the light confinement effect of the photonic crystal, and is emitted in the direction of the second light 82L.

For example, the base 10s includes a first face F1 facing the first electrode 51. The second light 82L obtained by changing the traveling direction of the first light 81L by the photonic crystal layer 12C is emitted from the first face F1. The first face F1 is a light emission surface.

As shown in FIG. 1, the light-emitting layer 18 is along a first plane PL1 that crosses the first direction D1. The first plane PL1 may correspond to, for example, the X-Y plane.

As shown in FIGS. 1 and 2, the first electrode 51 includes a first electrode portion 51A and a second electrode portion 51B. The second electrode portion 51B is provided around the first electrode portion 51A along the first plane PL1. The first electrode portion 51A corresponds to, for example, a central portion. The second electrode portion 51B corresponds to, for example, an outer edge portion.

As shown in FIG. 1, the first electrode portion 51A includes a first conductive layer 51a and a second conductive layer 51b. The second conductive layer 51b is between the first conductive layer 51a and the base 10s. For example, the first conductive layer 51a may be in contact with the base 10s.

The second electrode portion 51B includes a third conductive layer 51c and a fourth conductive layer 51d. The fourth conductive layer 51d is between the third conductive layer 51c and the base 10s. For example, the third conductive layer 51c may be in contact with the base 10s.

In the embodiment, a second optical absorptance of the second conductive layer 51b at the first wavelength λ1 is higher than a fourth optical absorptance of the fourth conductive layer 51d at the first wavelength λ1. This provides a high light extraction efficiency. For example, a high output is obtained. According to the embodiment, a surface-emitting laser with improved characteristics can be provided.

For example, a first reference example can be considered in which the optical absorptance of the first electrode 51 is high in the central portion of the light emission surface and in the peripheral portion around the central portion. In the first reference example, light emitted from the light-emitting layer 18 and reaches the first face F1 via the photonic crystal layer 12C is absorbed and lost in the first electrode 51. It is difficult to obtain high light extraction efficiency.

On the other hand, a second reference example can be considered in which the light absorptance of the first electrode 51 is low in the central portion of the light-emitting surface and in the peripheral portion of the light-emitting surface. In the second reference example, the light reflectance of the first electrode 51 is high. In the second reference example, the light is reflected at the central portion where the light reflectance is high, causing interference. The intensity of the light decreases due to interference depending on the optical path length. If the optical path length is appropriately set, it is possible to suppress the decrease in the intensity of the light due to interference. However, since high-precision control of the optical path length is required, this is not practical enough. Interference is a phenomenon unique to lasers. Suppressing interference is a problem unique to lasers. This problem is particularly likely to occur in the central portion where the light is incident perpendicularly.

In the embodiment, the light absorptance of the first electrode 51 is different between the central portion of the light-emitting surface and the peripheral portion around the central portion. That is, a second light absorptance of the second conductive layer 51b is set higher than a fourth light absorptance of the fourth conductive layer 51d. This appropriately suppresses interference in the central portion where the light intensity is high. Light loss is suppressed.

On the other hand, in the embodiment, in the peripheral portion where the light intensity is low, loss due to interference is unlikely to be a problem. In the peripheral portion where the light intensity is low, the fourth light absorptance of the fourth conductive layer 51d may be set low. In the peripheral portion where the fourth conductive layer 51d is provided, light is incident on the fourth conductive layer 51d in an inclined direction. This makes it less likely that interference will occur. In the fourth conductive layer 51d, reflection with high reflectance is utilized with low light absorptance, and the light utilization efficiency can be improved. According to the embodiment, a high light output can be obtained. The characteristics can be improved.

In the embodiment, a fourth conductivity of the fourth conductive layer 51d may be higher than a second conductivity of the second conductive layer 51b. By the electrical resistance of the outer edge portion being low, current can be injected uniformly over a wide range of the first face F1. For example, by the second conductivity of the second conductive layer 51b being low, it becomes easy to select a material applied to the second conductive layer 51b from the viewpoint of high light absorptance.

In one example, the second conductive layer 51b includes titanium. The fourth conductive layer 51d includes nickel. The second conductive layer 51b including titanium provides high light absorptance. The second conductive layer 51b including titanium provides high adhesion. The fourth conductive layer 51d including nickel provides high reflectance and high conductivity. The fourth conductive layer 51d including nickel provides high adhesion.

The first conductive layer 51a may include at least one selected from the group consisting of gold, silver, and aluminum, for example. The third conductive layer 51c may include at least one selected from the group consisting of gold, silver, and aluminum, for example. The material of the third conductive layer 51c may be the same as the material of the first conductive layer 51a.

As shown in FIG. 1, a thickness of the second conductive layer 51b is defined as a second thickness t2. The second thickness t2 is preferably not less than 20 nm and not more than 50 nm. By the second thickness t2 being 20 nm or more, for example, light can be efficiently absorbed and interference can be effectively suppressed. By the second thickness t2 being 50 nm or less, low electrical resistance can be maintained.

A thickness of the first conductive layer 51a is defined as a first thickness t1. The first thickness t1 may be, for example, not less than 200 nm and not more than 400 nm. A thickness of the third conductive layer 51c is defined as a third thickness t3. The third thickness t3 may be, for example, not less than 200 nm and not more than 400 nm. A thickness of the fourth conductive layer 51d is defined as a fourth thickness t4. The fourth thickness t4 may be, for example, not less than 10 nm and not more than 50 nm. Various modifications of these thicknesses are possible.

As shown in FIGS. 1 and 2, the first face F1 includes a first face portion Fp1 and a second face portion Fp2. The first face portion Fp1 overlaps the first electrode portion 51A in the first direction D1. The second face portion Fp2 does not overlap the first electrode portion 51A in the first direction D1. The second light 82L is emitted to the outside from the second face portion Fp2.

As shown in FIGS. 1 and 2, the first face portion Fp1 is between a part of the second face portion Fp2 and another part of the second face portion Fp2. As shown in FIG. 2, a direction from the part of the second face portion Fp2 to the other part of the second face portion Fp2 is defined as a second direction D2. The second direction D2 may be the X-axis direction. As shown in FIG. 1, a length of the first face portion Fp1 in the second direction D2 is defined as a first length L1. A length of a part of the second face portion Fp2 in the second direction D2 is defined as a second length L2. The first length L1 may be shorter than the second length L2. At least a part of the first electrode portion 51A may correspond to a thin wire electrode.

As shown in FIG. 2, the first electrode portion 51A may include a radiation portion 51R. At least a part of the radiation portion 51R is aligned in an axial direction from the central portion 51cc surrounded by the second electrode portion 51B to the outside. At least a part of the radiation portion 51R corresponds to a thin wire electrode.

As shown in FIG. 1, the stacked body SB1 may include a first semiconductor layer 11. The first semiconductor layer 11 is provided between the base 10s and the light-emitting layer 18. The first semiconductor layer 11 includes a first partial region 11p and a second partial region 11q. A direction from the first partial region 11p to the second partial region 11q crosses the first direction D1. The light-emitting layer 18 is between the first partial region 11p and the second electrode 52 in the first direction D1. The light-emitting layer 18 does not overlap with the second partial region 11q in the first direction D1. The stacked body SB1 has, for example, a mesa structure. The first semiconductor layer 11 may function as a cladding layer.

In this example, the stacked body SB1 further includes a fourth semiconductor layer 14. The fourth semiconductor layer 14 is provided between the first semiconductor layer 11 (first partial region 11p) and the light-emitting layer 18. The fourth semiconductor layer 14 may function as, for example, a guide layer.

The light-emitting layer 18 includes a plurality of first semiconductor films 18a and a plurality of second semiconductor films 18b. The plurality of first semiconductor films 18a include In_{z1}Ga_{1-z1}As (0<z1<1) . The plurality of second semiconductor films 18b include In_{z2}Al_{1-z2}As (0<z2<1). One of the plurality of first semiconductor films 18a is between one of the plurality of second semiconductor films 18b and another one of the plurality of second semiconductor films 18b in the first direction D1. One of the second semiconductor films 18b is between one of the first semiconductor films 18a and another one of the first semiconductor films 18a in the first direction D1. The first semiconductor films 18a and the second semiconductor films 18b may be provided alternately.

The light-emitting layer 18 may be configured to emit light by intersubband transition. The surface-emitting laser 110 may be, for example, a surface-emitting quantum cascade laser (QCL).

The photonic crystal layer 12C includes a second semiconductor layer 12 and a third semiconductor layer 13. The third semiconductor layer 13 is provided between the second semiconductor layer 12 and the second electrode 52. The second semiconductor layer 12 includes a plurality of second semiconductor regions 12p arranged along the first plane PL1. The plurality of second semiconductor regions 12p may correspond to, for example, a protrusion. At least a part (a portion 13p) of the third semiconductor layer 13 is between one of the plurality of second semiconductor regions 12p and another one of the plurality of second semiconductor regions 12p. A third refractive index of the third semiconductor layer 13 is different from a second refractive index of the second semiconductor layer 12. The difference in the refractive index changes the traveling direction of the light.

The second semiconductor layer 12 includes, for example, Inₓ₂Ga₁₋ₓ₂As (0<x2<1). The second semiconductor layer 12 includes, for example, InGaAs. The third semiconductor layer 13 includes InP. The third semiconductor layer 13 may function as a cladding layer.

The first semiconductor layer 11 includes, for example, InP. The fourth semiconductor layer 14 includes, for example, Inₓ₄Ga₁₋ₓ₄As (0<x4<1). The fourth semiconductor layer 14 includes, for example, InGaAs. The base 10s includes, for example, InP.

The first wavelength λ1 of the first light 81L emitted from the light-emitting layer 18 may be, for example, not less than 2 μm and not more than 10 μm.

The thickness t11 of the first semiconductor layer 11 may be, for example, not less than 2 μm and not more than 3 μm. The thickness t14 of the fourth semiconductor layer 14 may be, for example, not less than 0.1 μm and not more than 0.5 μm. The thickness t18 of the light-emitting layer 18 may be, for example, not less than 1 μm and not more than 2 μm. The thickness t12 of the second semiconductor layer 12 may be, for example, not less than 0.5 μm and not more than 2 μm. The thickness t13 of the third semiconductor layer 13 may be, for example, not less than 1.5 μm and not more than 4 μm.

The surface-emitting laser 110 may include an insulating member 31. The insulating member 31 includes, for example, a first insulating region 31a and a second insulating region 31b. The light-emitting layer 18 and the photonic crystal layer 12C are between the first insulating region 31a and the second insulating region 31b in a direction crossing the first direction D1. Stable operation is obtained.

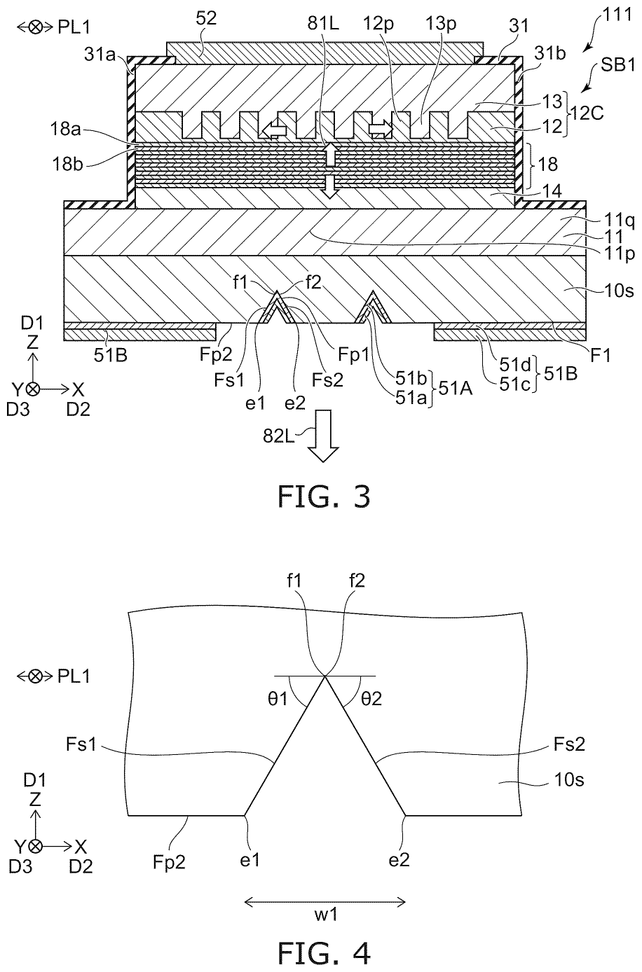

FIG. 3 is a schematic cross-sectional view illustrating a surface-emitting laser according to the first embodiment.

As shown in FIG. 3, in a surface-emitting laser 111 according to the embodiment, the first face portion Fp1 is inclined with respect to the first plane PL1. The configuration of the surface-emitting laser 111 except for this may be the same as the configuration of the surface-emitting laser 110.

In the surface-emitting laser 111, the first face portion Fp1 includes a first side face Fs1. The first side face Fs1 is inclined with respect to the first plane PL1. A part of the second conductive layer 51b is between a part of the first conductive layer 51a and the first side face Fs1. Light incident on the first side face Fs1 changes its traveling direction and is reflected by the first side face Fs1. This makes it possible to more effectively suppress interference. A higher optical output can be obtained. The characteristics can be further improved.

As shown in FIG. 3, the first face portion Fp1 may further include a second side face Fs2. The second side face Fs2 may be inclined with respect to the first plane PL1. The second side face Fs2 may be along the first direction D1. Another part of the second conductive layer 51b is between another part of the first conductive layer 51a and the second side face Fs2. The second side face Fs2 suppresses reflection. Interference can be suppressed more effectively. Higher optical output can be obtained. Characteristics can be further improved.

FIG. 4 is a schematic cross-sectional view illustrating a part of the surface-emitting laser according to the first embodiment.

As shown in FIG. 4, the first side face Fs1 includes a first end e1 and a first other end f1. The second side face Fs2 includes a second end e2 and a second other end f2. The first end e1 is connected to the second face portion Fp2. The first other end f1 is connected to the second other end f2. The first end e1 is between the second face portion Fp2 and the second end e2. As shown in FIG. 4, a position of the first other end f1 in the first direction D1 (first other end position) is between a position of the first end e1 in the first direction D1 (first end position) and a position of the second electrode 52 in the first direction D1 (second electrode position). For example, the first side face Fs1 and the second side face Fs2 are inclined recesses.

As shown in FIG. 4, an angle between the first plane PL1 and the first side face Fs1 is defined as a first angle θ1. In one example, the refractive index of the base 10s is 3.1, and the refractive index of the medium (e.g., the outside) into which the light is emitted is 1. In this case, the first angle θ1 may be not less than 18.82 degrees and not more than 80.59 degrees. For example, light that is incident on the first side face Fs1 along the first direction D1 is totally reflected. For example, two total reflections are obtained. Light is extracted with high efficiency. Under practical conditions, the first angle θ1 is preferably not less than 15 degrees and not more than 85 degrees.

An angle between the first plane PL1 and the second side face Fs2 is defined as a second angle θ2. In one example, the refractive index of the base 10s is 3.1, and the refractive index of the medium (e.g., the outside) into which the light is emitted is 1. In this case, the second angle θ2 may be not less than 18.82 degrees and not more than 80.59 degrees. In practical conditions, the second angle θ2 is preferably not less than 15 degrees and not more than 85 degrees. The second angle θ2 may be the same as the first angle θ1. The second angle θ2 may be different from the first angle θ1.

The first plane PL1 may be along the second direction D2 and the third direction D3. The third direction D3 crosses a plane including the first direction D1 and the second direction D2.

As shown in FIG. 4, a distance between the first end e1 and the second end e2 is defined as a distance w1. The distance w1 may be not less than 0.1 times and not more than 5 times the first wavelength λ1.

### Second Embodiment

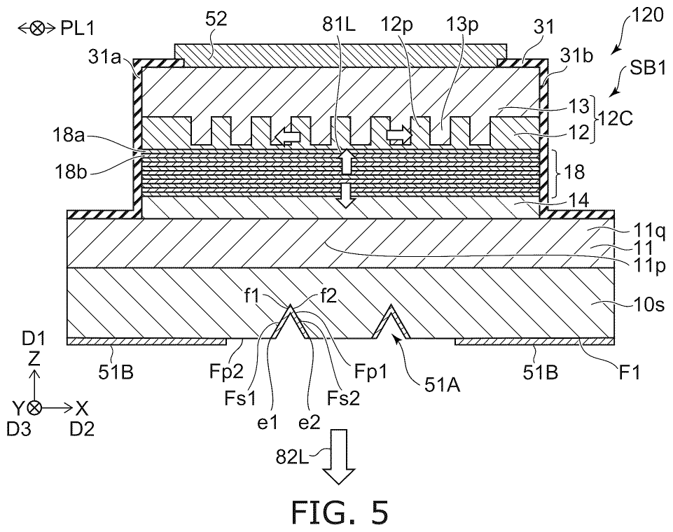

FIG. 5 is a schematic cross-sectional view illustrating a surface-emitting laser according to a second embodiment.

As shown in FIG. 5, a surface-emitting laser 120 according to the embodiment includes the first electrode 51, the second electrode 52, and the stacked body SB1. The stacked body SB1 is provided between the first electrode 51 and the second electrode 52 in the first direction D1 from the first electrode 51 to the second electrode 52.

The stacked body SB1 includes the base 10s, the light-emitting layer 18, and the photonic crystal layer 12C. The light-emitting layer 18 is provided between the base 10s and the second electrode 52, and is configured to emit the first light 81L including the first wavelength λ1. The photonic crystal layer 12C is provided between the light-emitting layer 18 and the second electrode 52. The light-emitting layer 18 is along the first plane PL1 that crosses the first direction D1.

The base 10s includes the first face F1 that faces the first electrode 51. The second light 82L obtained by changing the direction of travel of the first light 81L by the photonic crystal layer 12C is emitted from the first face F1.

The first electrode 51 includes a first electrode portion 51A. The first face F1 includes the first face portion Fp1 and the second face portion Fp2. The first face portion Fp1 overlaps the first electrode portion 51A in the first direction D1. The second face portion Fp2 does not overlap the first electrode portion 51A in the first direction D1. The second light 82L is emitted from the second face portion Fp2.

The first face portion Fp1 includes the first side face Fs1 and the second side face Fs2. The first side face Fs1 is inclined with respect to the first plane PL1. In this example, the second side face Fs2 is inclined with respect to the first plane PL1. The second side face Fs2 may be aligned along the first direction D1.

The first side face Fs1 includes the first end e1 and the first other end f1. The second side face Fs2 includes the second end e2 and the second other end f2. The first end e1 is connected to the second face portion Fp2. The first other end f1 is connected to the second other end f2. The first end e1 is between the second face portion Fp2 and the second end e2. The position of the first other end f1 in the first direction D1 (first other end position) is between the position of the first end e1 in the first direction D1 (first end position) and the position of the second electrode 52 in the first direction D1 (second electrode position).

In the surface-emitting laser 120, the first side face Fs1 changes the direction of light travel. For example, interference is suppressed. For example, high light output is obtained. A surface-emitting laser capable of improving characteristics is provided.

The first angle θ1 (see FIG. 4) between the first plane PL1 and the first side face Fs1 may be not less than 15 degrees and not more than 85 degrees under practical conditions. For example, light incident on the first side face Fs1 along the first direction D1 is totally reflected. Light is extracted with high efficiency. The second angle θ2 (see FIG. 4) between the first plane PL1 and the second side face Fs2 may be not less than 15 degrees and not more than 85 degrees under practical conditions. The second angle θ2 may be the same as the first angle θ1. The second angle θ2 may be different from the first angle θ1.

The configuration described in relation to the first embodiment may be applied to the surface-emitting laser 120.

In the embodiment, information on the shape of the electrodes and the stacked body is obtained, for example, by observation with an electron microscope. Information regarding the composition and element concentrations in the electrodes and stacked body can be obtained by, for example, energy dispersive X-ray spectroscopy (EDX) or secondary ion mass spectrometry (SIMS).

The embodiment may include the following Technical proposals:

### (Technical Proposal 1)

A surface-emitting laser, comprising:
a first electrode;
a second electrode; and
a stacked body provided between the first electrode and the second electrode in a first direction from the first electrode to the second electrode,
the stacked body including:
   a base;
   a light-emitting layer provided between the base and the second electrode and configured to emit a first light including a component having a first wavelength; and
   a photonic crystal layer provided between the light-emitting layer and the second electrode,
the light-emitting layer being along a first plane crossing the first direction,
the first electrode including a first electrode portion and a second electrode portion,
the second electrode portion being provided around the first electrode portion along the first plane,
the first electrode portion including a first conductive layer and a second conductive layer,
the second conductive layer being between the first conductive layer and the base,
the second electrode portion including a third conductive layer and a fourth conductive layer,
the fourth conductive layer being between the third conductive layer and the base, and
a second optical absorptance of the second conductive layer at the first wavelength being higher than a fourth optical absorptance of the fourth conductive layer at the first wavelength.

### (Technical Proposal 2)

The surface-emitting laser according to Technical proposal 1, wherein
a fourth conductivity of the fourth conductive layer is higher than a second conductivity of the second conductive layer.

### (Technical Proposal 3)

The surface-emitting laser according to Technical proposal 1 or 2, wherein
the second conductive layer includes titanium, and
the fourth conductive layer includes nickel.

### (Technical Proposal 4)

The surface-emitting laser according to Technical proposal 3, wherein
the first conductive layer includes at least one selected from the group consisting of gold, silver, and aluminum.

### (Technical Proposal 5)

The surface-emitting laser according to Technical proposal 2, wherein
a thickness of the second conductive layer is not less than 20 nm and not more than 50 nm.

### (Technical Proposal 6)

The surface-emitting laser according to any one of Technical proposals 1-5, wherein
the substrate includes a first face facing the first electrode, and
a second light obtained by changing a direction of travel of the first light by the photonic crystal layer is emitted from the first face.

### (Technical Proposal 7)

The surface-emitting laser according to Technical proposal 6, wherein
the first face includes a first face portion and a second face portion,
the first face portion overlaps the first electrode portion in the first direction, and
the second face portion does not overlap the first electrode portion in the first direction.

### (Technical Proposal 8)

The surface-emitting laser according to Technical proposal 7, wherein
the first face portion is between a part of the second face portion and another part of the second face portion, and
a first length of the first face portion in a second direction from the part of the second face portion to the other part of the second face portion is shorter than a second length of the part of the second face portion in the second direction.

### (Technical Proposal 9)

The surface-emitting laser according to any one of Technical proposals 1-8, wherein
the first electrode portion includes a radiation portion, and at least a part of the radiation portion is along an axial direction from a central portion surrounded by the second electrode portion to outside.

### (Technical Proposal 10)

The surface-emitting laser according to any one of Technical proposals 1-9, wherein
the stacked body includes a first semiconductor layer provided between the base and the light-emitting layer,
the first semiconductor layer includes a first partial region and a second partial region,
a direction from the first partial region to the second partial region crosses the first direction,
the light-emitting layer is between the first partial region and the second electrode in the first direction, and
the light-emitting layer does not overlap the second partial region in the first direction.

### (Technical Proposal 11)

The surface-emitting laser according to Technical proposal 7, wherein
the first face portion includes a first side face being inclined with respect to the first plane, and
a part of the second conductive layer is between a part of the first conductive layer and the first side face.

### (Technical Proposal 12)

The surface-emitting laser according to Technical proposal 11, wherein
the first face portion further includes a second side face,
another part of the second conductive layer is between the other part of the first conductive layer and the second side face,
the first side face includes a first end and a first other end,
the second side face includes a second end and a second other end,
the first end is connected to the second face portion,
the first other end is connected to the second other end,
the first end is between the second face portion and the second end, and
a first other end position of the first other end in the first direction is between a first end position of the first end in the first direction and a second electrode position of the second electrode in the first direction.

### (Technical Proposal 13)

The surface-emitting laser according to Technical proposal 12, wherein
a first angle between the first plane and the first side face is not less than 15 degrees and not more than 85 degrees.

### (Technical Proposal 14)

A surface-emitting laser, comprising:
a first electrode;
a second electrode; and
a stacked body provided between the first electrode and the second electrode in a first direction from the first electrode to the second electrode,
the stacked body including:
   a base;
   a light-emitting layer provided between the base and the second electrode and configured to emit a first light including a component having a first wavelength, and
   a photonic crystal layer provided between the light-emitting layer and the second electrode,
the light-emitting layer being along a first plane crossing the first direction,
the base including a first face facing the first electrode,
a second light obtained by changing a direction of travel of the first light by the photonic crystal layer being emitted from the first face,
the first electrode including a first electrode portion,
the first face including a first face portion and a second face portion,
the first face portion overlapping the first electrode portion in the first direction,
the second face portion not overlapping the first electrode portion in the first direction,
the first face portion including a first side face and a second side face,
the first side face being inclined with respect to the first plane,
the first side face including a first end and a first other end,
the second side face including a second end and a second other end,
the first end being connected to the second face portion,
the first other end being connected to the second other end,
the first end being between the second face portion and the second end, and
a first other end position of the first other end in the first direction being between a first end position of the first end in the first direction and a second electrode position of the second electrode in the first direction.

### (Technical Proposal 15)

The surface-emitting laser according to Technical proposal 14, wherein
a first angle between the first plane and the first side face is not less than 15 degrees and not more than 85 degrees.

### (Technical Proposal 16)

The surface-emitting laser according to any one of technical proposals 1-15, wherein
the light-emitting layer is configured to emit light by intersubband transition.

### (Technical Proposal 17)

The surface-emitting laser according to any one of Technical proposals 1-16, wherein
The light-emitting layer includes:
   a plurality of first semiconductor films including In_{z1}Ga_{1-z1}As (0<z1<1); and
   a plurality of second semiconductor films including In_{z2}Al_{1-z2}As (0<z2<1),
one of the first semiconductor films is between one of the second semiconductor films and another one of the second semiconductor films in the first direction, and
the one of the second semiconductor films is between the one of the first semiconductor films and another one of the first semiconductor films in the first direction.

### (Technical Proposal 18)

The surface-emitting laser according to Technical proposal 10, wherein
the photonic crystal layer includes:
   a second semiconductor layer; and
   a third semiconductor layer provided between the second semiconductor layer and the second electrode,
the second semiconductor layer includes a plurality of second semiconductor regions arranged along the first plane,
at least a part of the third semiconductor layer is between one of the plurality of second semiconductor regions and another one of the plurality of second semiconductor regions, and
a third refractive index of the third semiconductor layer is different from a second refractive index of the second semiconductor layer.

### (Technical Proposal 19)

The surface-emitting laser according to Technical proposal 18, wherein
the second semiconductor layer includes Inₓ₂Ga₁₋ₓ₂As (0<x2<1), and
the third semiconductor layer includes InP.

### (Technical Proposal 20)

The surface-emitting laser according to Technical proposal 19, wherein
the stacked body further includes a fourth semiconductor layer provided between the first semiconductor layer and the light-emitting layer,
the fourth semiconductor layer includes Inₓ₄ga₁₋ₓ₄As (0<x4<1).

According to the embodiment, a surface-emitting laser with improved characteristics can be provided.

In this specification, “vertical” and “parallel” do not only mean strictly vertical and strictly parallel, but also include, for example, variations in the manufacturing process, and can mean substantially vertical and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the surface-emitting lasers such as electrode, stacked bodies, semiconductor layers, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all surface-emitting lasers practicable by an appropriate design modification by one skilled in the art based on the surface-emitting lasers described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A surface-emitting laser, comprising:
a first electrode;
a second electrode; and
a stacked body provided between the first electrode and the second electrode in a first direction from the first electrode to the second electrode,
the stacked body including:
a base;
a light-emitting layer provided between the base and the second electrode and configured to emit a first light including a component having a first wavelength; and
a photonic crystal layer provided between the light-emitting layer and the second electrode,
the light-emitting layer being along a first plane crossing the first direction,
the first electrode including a first electrode portion and a second electrode portion,
the second electrode portion being provided around the first electrode portion along the first plane,
the first electrode portion including a first conductive layer and a second conductive layer,
the second conductive layer being between the first conductive layer and the base,
the second electrode portion including a third conductive layer and a fourth conductive layer,
the fourth conductive layer being between the third conductive layer and the base, and
a second optical absorptance of the second conductive layer at the first wavelength being higher than a fourth optical absorptance of the fourth conductive layer at the first wavelength.

2. The surface-emitting laser according to claim 1, wherein
a fourth conductivity of the fourth conductive layer is higher than a second conductivity of the second conductive layer.

3. The surface-emitting laser according to claim 1, wherein
the second conductive layer includes titanium, and
the fourth conductive layer includes nickel.

4. The surface-emitting laser according to claim 3, wherein
the first conductive layer includes at least one selected from the group consisting of gold, silver, and aluminum.

5. The surface-emitting laser according to claim 2, wherein
a thickness of the second conductive layer is not less than 20 nm and not more than 50 nm.

6. The surface-emitting laser according to claim 1, wherein
the substrate includes a first face facing the first electrode, and
a second light obtained by changing a direction of travel of the first light by the photonic crystal layer is emitted from the first face.

7. The surface-emitting laser according to claim 6, wherein
the first face includes a first face portion and a second face portion,
the first face portion overlaps the first electrode portion in the first direction, and
the second face portion does not overlap the first electrode portion in the first direction.

8. The surface-emitting laser according to claim 7, wherein
the first face portion is between a part of the second face portion and another part of the second face portion, and
a first length of the first face portion in a second direction from the part of the second face portion to the other part of the second face portion is shorter than a second length of the part of the second face portion in the second direction.

9. The surface-emitting laser according to claim 1, wherein
the first electrode portion includes a radiation portion, and
at least a part of the radiation portion is along an axial direction from a central portion surrounded by the second electrode portion to outside.

10. The surface-emitting laser according to claim 1, wherein
the stacked body includes a first semiconductor layer provided between the base and the light-emitting layer,
the first semiconductor layer includes a first partial region and a second partial region,
a direction from the first partial region to the second partial region crosses the first direction,
the light-emitting layer is between the first partial region and the second electrode in the first direction, and
the light-emitting layer does not overlap the second partial region in the first direction.

11. The surface-emitting laser according to claim 7, wherein
the first face portion includes a first side face being inclined with respect to the first plane, and
a part of the second conductive layer is between a part of the first conductive layer and the first side face.

12. The surface-emitting laser according to claim 11, wherein
the first face portion further includes a second side face,
another part of the second conductive layer is between the other part of the first conductive layer and the second side face,
the first side face includes a first end and a first other end,
the second side face includes a second end and a second other end,
the first end is connected to the second face portion,
the first other end is connected to the second other end,
the first end is between the second face portion and the second end, and
a first other end position of the first other end in the first direction is between a first end position of the first end in the first direction and a second electrode position of the second electrode in the first direction.

13. The surface-emitting laser according to claim 12, wherein
a first angle between the first plane and the first side face is not less than 15 degrees and not more than 85 degrees.

14. A surface-emitting laser, comprising:
a first electrode;
a second electrode; and
a stacked body provided between the first electrode and the second electrode in a first direction from the first electrode to the second electrode,
the stacked body including:
a base;
a light-emitting layer provided between the base and the second electrode and configured to emit a first light including a component having a first wavelength, and
a photonic crystal layer provided between the light-emitting layer and the second electrode,
the light-emitting layer being along a first plane crossing the first direction,
the base including a first face facing the first electrode,
a second light obtained by changing a direction of travel of the first light by the photonic crystal layer being emitted from the first face,
the first electrode including a first electrode portion,
the first face including a first face portion and a second face portion,
the first face portion overlapping the first electrode portion in the first direction,
the second face portion not overlapping the first electrode portion in the first direction,
the first face portion including a first side face and a second side face,
the first side face being inclined with respect to the first plane,
the first side face including a first end and a first other end,
the second side face including a second end and a second other end,
the first end being connected to the second face portion,
the first other end being connected to the second other end,
the first end being between the second face portion and the second end, and
a first other end position of the first other end in the first direction being between a first end position of the first end in the first direction and a second electrode position of the second electrode in the first direction.

15. The surface-emitting laser according to claim 14, wherein
a first angle between the first plane and the first side face is not less than 15 degrees and not more than 85 degrees.

16. The surface-emitting laser according to claim 1, wherein
the light-emitting layer is configured to emit light by intersubband transition.

17. The surface-emitting laser according to claim 1, wherein
The light-emitting layer includes:
a plurality of first semiconductor films including In_{z1}Ga_{1-z1}As (0<z1<1); and
a plurality of second semiconductor films including In_{z2}Al_{1-z2}As (0<z2<1),
one of the first semiconductor films is between one of the second semiconductor films and another one of the second semiconductor films in the first direction, and
the one of the second semiconductor films is between the one of the first semiconductor films and another one of the first semiconductor films in the first direction.

18. The surface-emitting laser according to claim 10, wherein
the photonic crystal layer includes:
a second semiconductor layer; and
a third semiconductor layer provided between the second semiconductor layer and the second electrode,
the second semiconductor layer includes a plurality of second semiconductor regions arranged along the first plane,
at least a part of the third semiconductor layer is between one of the plurality of second semiconductor regions and another one of the plurality of second semiconductor regions, and
a third refractive index of the third semiconductor layer is different from a second refractive index of the second semiconductor layer.

19. The surface-emitting laser according to claim 18, wherein
the second semiconductor layer includes Inₓ₂Ga₁₋ₓ₂As (0<x2<1), and
the third semiconductor layer includes InP.

20. The surface-emitting laser according to claim 19, wherein
the stacked body further includes a fourth semiconductor layer provided between the first semiconductor layer and the light-emitting layer,
the fourth semiconductor layer includes Inₓ₄Ga₁₋ₓ₄As (0<x4<1).
